(19) United States
(12) Patent Application Publication
(10) Pub. No.: US 2017/0012006 A1
(43) Pub. Date: Jan. 12, 2017

(54) SEMICONDUCTOR INTEGRATED CIRCUIT

(71) Applicant: SOCIONEXT INC., Kanagawa (JP)

(72) Inventors: Yoshihiro OKUMURA, Osaka (JP); Yukio HIRAOKA, Hyogo (JP); Shinichirou YONEYAMA, Hyogo (JP); Miki YAMANAKA, Osaka (JP)

(21) Appl. No.: 15/276,390

(22) Filed: Sep. 26, 2016

Related U.S. Application Data
(63) Continuation of application No. PCT/JP2014/006142, filed on Dec. 9, 2014.

(30) Foreign Application Priority Data
Mar. 28, 2014 (JP) 2014-068902

(51) Int. Cl. H01L 23/58; H01L 29/06

(52) U.S. Cl. CPC H01L 23/585; H01L 29/0649

(57) ABSTRACT

A high-resistance region is formed right under a seal ring by irradiating a semiconductor substrate with hydrogen ions or helium ions. The high-resistance region has a greater thickness than an isolation insulating layer formed as a shallow trench isolation (STI) region on the surface of the semiconductor substrate. As a result, a semiconductor integrated circuit including a seal ring achieving excellent high-frequency isolation is provided.

### CROSS-REFERENCE TO RELATED APPLICATIONS

This is a continuation of International Application No. PCT/JP2014/006142 filed on Dec. 9, 2014, which claims priority to Japanese Patent Application No. 2014-068902 filed on Mar. 28, 2014. The entire disclosures of these applications are hereby incorporated by reference.

### BACKGROUND

The present disclosure relates to semiconductor integrated circuits including a seal ring.

According to a known technique, a seal ring made of a multilayer metal is, as a moisture-proof ring, formed on an isolation insulating layer, which serves as a shallow trench isolation (STI) region in the surface of a semiconductor substrate (see Japanese Unexamined Patent Publication No. 2011-49214).

### SUMMARY

According to the known technique, propagation of low-frequency noise from a digital circuit through the seal ring to an analog circuit on the semiconductor substrate, for example, is reduced by the high-resistance STI region. However, the STI region usually has so small a thickness and so large a capacitance value that high-frequency noise cannot be reduced effectively by the known technique.

The present disclosure provides a semiconductor integrated circuit including a seal ring achieving excellent high-frequency isolation.

A semiconductor integrated circuit according to the present disclosure includes a semiconductor substrate; a first circuit formed on the semiconductor substrate; a seal ring formed on the semiconductor substrate to surround at least part of the first circuit; and a high-resistance region formed on a propagation path of noise leaking out of or into the first circuit through the seal ring in the semiconductor substrate to have a higher resistivity than a surrounding region. The high-resistance region is formed by irradiating the semiconductor substrate with ions. For example, the high-resistance region contains hydrogen or helium used for ion irradiation of the semiconductor substrate to increase resistance.

According to the present disclosure, the high-resistance region formed by irradiating the semiconductor substrate with ions reduces noise propagation through the seal ring. The thickness of the high-resistance region may easily be set to be greater than that of the STI region, thereby increasing resistance and reducing capacitance, at the same time. This results in reduction in both low- and high-frequency noise.

### BRIEF DESCRIPTION OF THE DRAWINGS

FIG. 1 is a plan view of a semiconductor integrated circuit according to a first embodiment of the present disclosure.

FIG. 2A is an enlarged cross-sectional view taken along the plane II-II of FIG. 1. FIGS. 2B, 2C, 2D, and 2E are enlarged cross-sectional views according to variations of the semiconductor integrated circuit.

FIG. 3 is an enlarged cross-sectional view illustrating an exemplary detailed cross-sectional structure of the semiconductor integrated circuit of FIG. 1.

FIG. 4 is a plan view illustrating a first variation of the semiconductor integrated circuit of FIG. 1.

FIG. 5 is a plan view illustrating a second variation of the semiconductor integrated circuit of FIG. 1.

FIG. 6 is a plan view illustrating a third variation of the semiconductor integrated circuit of FIG. 1.

FIG. 7 is a plan view illustrating a fourth variation of the semiconductor integrated circuit of FIG. 1.

FIG. 8 is a plan view illustrating a fifth variation of the semiconductor integrated circuit of FIG. 1.

FIG. 9 is an enlarged cross-sectional view illustrating an exemplary method of forming a high-resistance region of FIG. 2C.

FIG. 10 is a cross-sectional view illustrating a variation of the method of forming the high-resistance region of FIG. 9.

FIG. 11 is a plan view of a semiconductor integrated circuit according to a second embodiment of the present disclosure.

FIG. 12 is an enlarged cross-sectional view taken along the plane XII-XII of FIG. 11.

FIG. 13 is a cross-sectional view illustrating a variation of the semiconductor integrated circuit of FIG. 11.

FIG. 14 is a cross-sectional view of a semiconductor integrated circuit according to a third embodiment of the present disclosure.

### DETAILED DESCRIPTION

Embodiments of the present disclosure will now be described in detail with reference to the drawings.

### First Embodiment

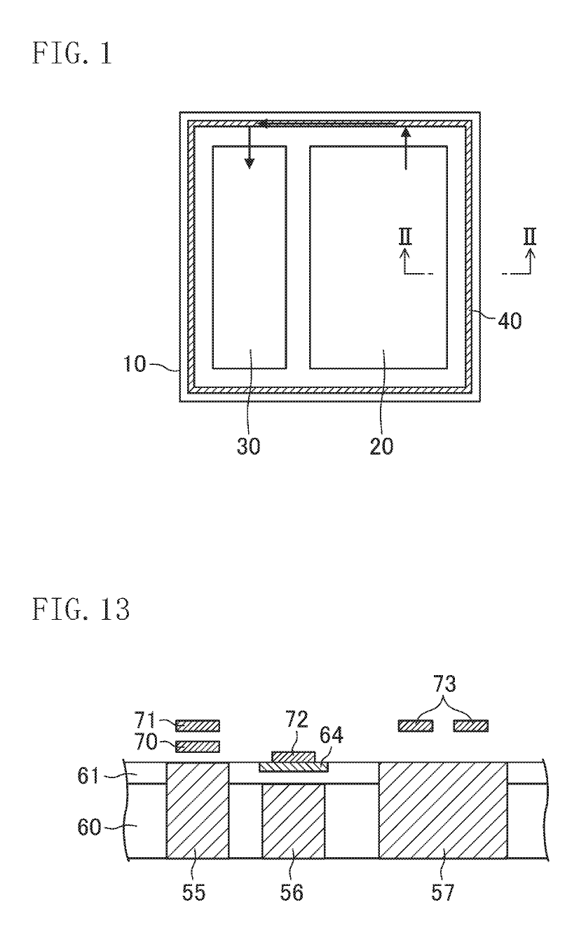

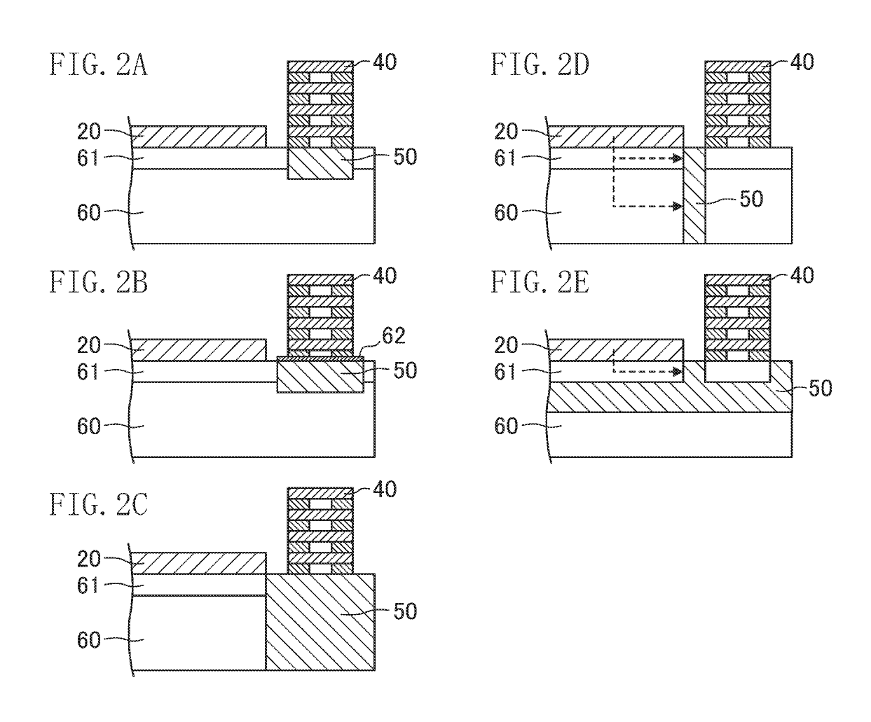

FIG. 1 is a plan view of a semiconductor integrated circuit according to a first embodiment of the present disclosure. FIG. 2A is an enlarged cross-sectional view taken along the plane II-II of FIG. 1. A semiconductor integrated circuit 10 includes a semiconductor substrate 60 and an n-well 61. The semiconductor substrate 60 is made of, for example, p-type semiconductor (Si). The n-well 61 is formed by implanting dopant ions into a surface region of the semiconductor substrate 60. A digital circuit 20 and an analog circuit 30 are formed on the semiconductor substrate 60. The digital circuit 20 may serve as a noise source. The analog circuit 30 is influenced by noise. A seal ring 40 is further formed on the semiconductor substrate 60 to surround the digital circuit 20 and the analog circuit 30. As shown in FIG. 2A, a high-resistance region 50 is formed right under the seal ring 40 in the semiconductor substrate 60. This high-resistance region 50 is formed to have a higher resistivity than the surrounding region by irradiating the semiconductor substrate 60 with ions. Specifically, the high-resistance region 50 is located within a depth of 10 μm from the surface of the semiconductor substrate 60, and is deeper than the n-well 61. Each of the seal ring 40 and the high-resistance region 50 is formed continuously to surround the digital circuit 20 and the analog circuit 30.

The high-resistance region 50 reduces, near the digital circuit 20, propagation of noise leaking out of the digital circuit 20 through the seal ring 40. The high-resistance region 50 also reduces, near the analog circuit 30, propagation of noise leaking into the analog circuit 30 through the seal ring 40.

FIGS. 2B, 2C, 2D, and 2E illustrate variations of FIG. 2A. In FIG. 2B, the high-resistance region 50 is located under a silicide layer 62 right under the seal ring 40. In FIG. 2C, the high-resistance region 50 extends from the principal surface to the back surface of the semiconductor substrate 60. In FIG. 2D, the high-resistance region 50 is located inside the region right under the seal ring 40 and outside the digital circuit 20. In such a manner, the region right under the seal ring 40 does not necessarily have high resistance. In FIG. 2E, the high-resistance region 50 has a first portion and a second portion. The first portion expands horizontally at a depth of 10 μm or more from the surface of the semiconductor substrate 60. Inside the region right under the seal ring 40 and outside the digital circuit 20, the second portion extends vertically from the surface of the semiconductor substrate 60 to the first portion.

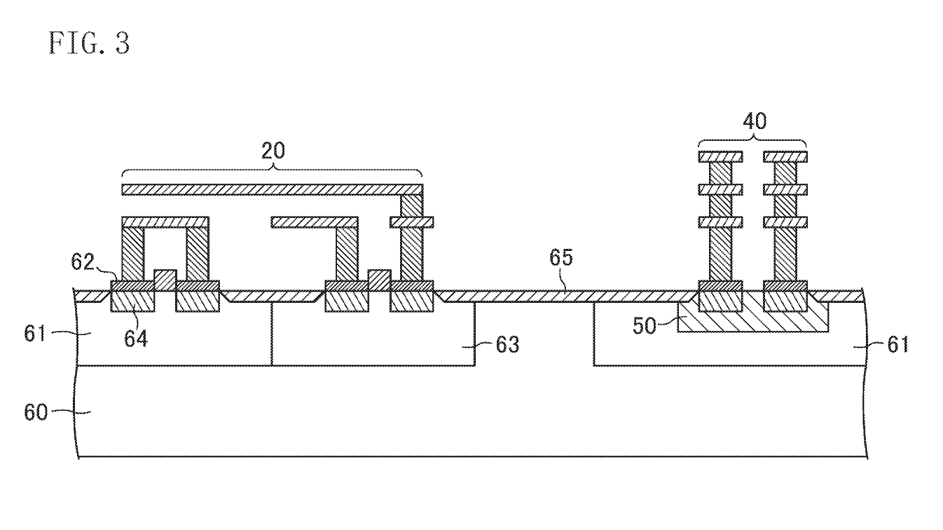

FIG. 3 illustrates an exemplary detailed cross-sectional structure of the semiconductor integrated circuit 10 of FIG. 1. In FIG. 3, reference numeral 20 denotes a digital circuit, and 40 denotes a seal ring. The semiconductor integrated circuit of FIG. 3 includes a semiconductor substrate 60, an n-well 61, and a p-well 63. The semiconductor substrate 60 is made of, for example, p-type semiconductor. The n-well 61 and the p-well 63 are formed on the surface of the semiconductor substrate 60. Doped regions 64 are formed in each of the n-well 61 and the p-well 63. A silicide layer 62 is formed on the doped regions 64. A multilayer interconnect structure for the digital circuit 20 is connected to the silicide layer 62. In addition, inside the region right under the seal ring 40 and outside the digital circuit 20, an isolation insulating layer 65 is provided as STI regions on the surface of the semiconductor substrate 60. The isolation insulating layer 65 is made of, for example, SiO₂. Interlayer insulating films are not shown in the figure.

The doped regions 64 are also formed in an n-well 61 under the seal ring 40. The silicide layer 62 is formed on the doped regions 64. A multilayer interconnect structure for the seal ring 40 is connected to the silicide layer 62. In the region right under the seal ring 40, a high-resistance region 50 with a larger thickness than the isolation insulating layer 65 is formed in the n-well 61. This high-resistance region 50 is formed to have a higher resistivity than the surrounding region by irradiating the semiconductor substrate 60 with ions.

The silicide layer 62 shown in FIG. 3 may be omitted. The seal ring 40 may be connected to the semiconductor substrate 60 via the p-well 63 instead of the n-well 61. Alternatively, the semiconductor substrate 60 may have no wells as well.

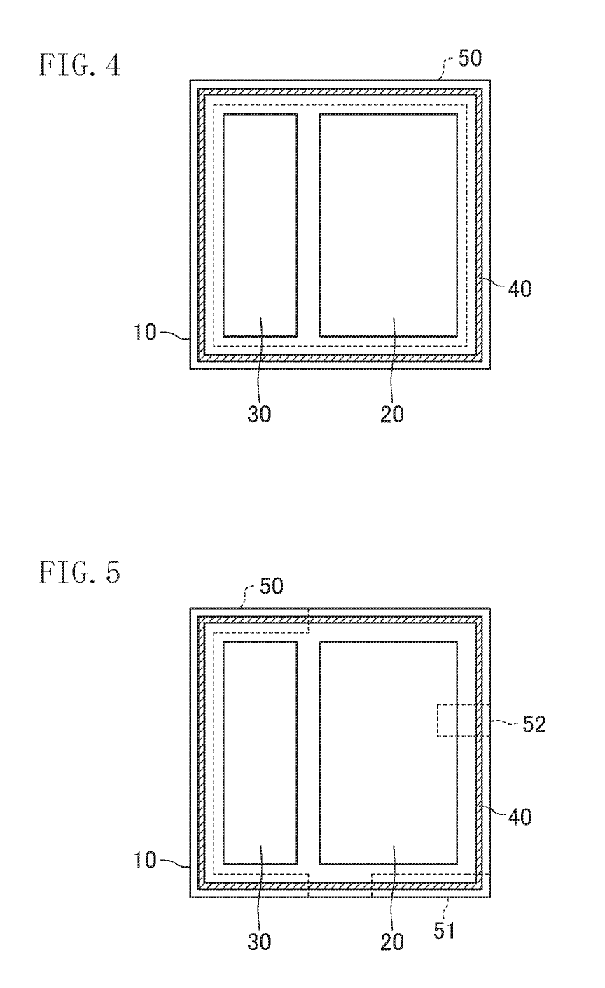

FIG. 4 illustrates a first variation of the semiconductor integrated circuit 10 of FIG. 1. In FIG. 4, the seal ring 40 and the high-resistance region 50 are formed continuously on the semiconductor substrate to surround the digital circuit 20 and the analog circuit 30. The high-resistance region 50 is wider than the seal ring 40.

FIG. 5 illustrates a second variation of the semiconductor integrated circuit 10 of FIG. 1. In FIG. 5, the seal ring 40 is formed continuously on the semiconductor substrate to surround the digital circuit 20 and the analog circuit 30. In this variation, however, high-resistance regions 50, 51, and 52 are formed discontinuously right under the seal ring 40. The high-resistance region 50 is positioned adjacent to the analog circuit 30. The high-resistance region 51 is positioned adjacent to a noise source in the digital circuit 20. The high-resistance region 52 extends to reach a region under the digital circuit 20 to cut off the noise propagating through the seal ring 40. In this manner, if any one of the high-resistance regions 50, 51, and 52 is provided in a position so as to reduce at least one of the noise leaking out of the digital circuit 20 through the seal ring 40, the noise propagating through the seal ring 40, and the noise leaking into the analog circuit 30 through the seal ring 40. This reduces propagation of the noise leaking out of the digital circuit 20 through the seal ring 40 into the analog circuit 30.

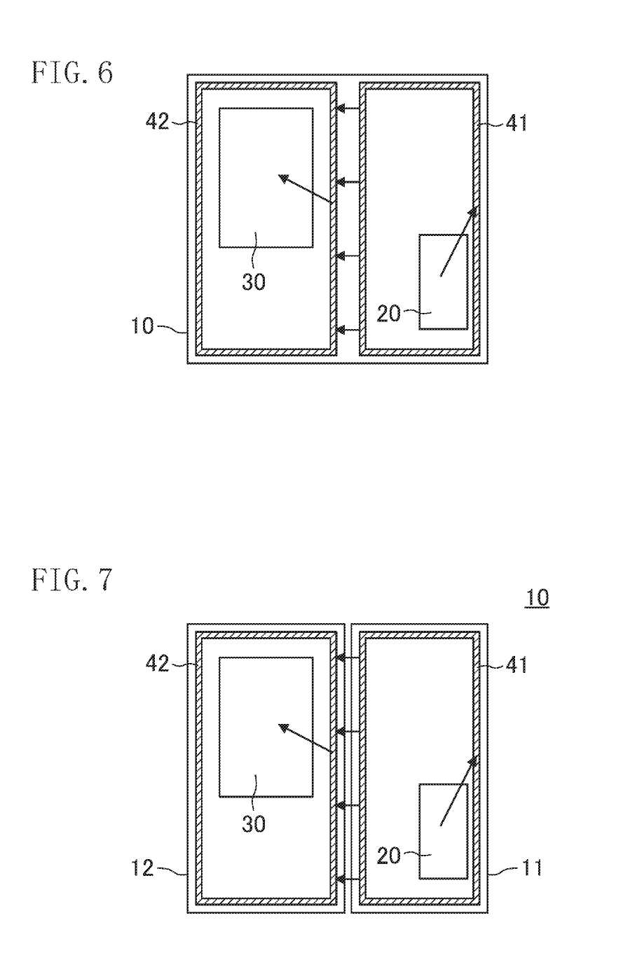

FIG. 6 illustrates a third variation of the semiconductor integrated circuit 10 of FIG. 1. In FIG. 6, the seal ring on the semiconductor substrate is divided into a first seal ring 41 and a second seal ring 42. The first seal ring 41 is formed continuously to surround the digital circuit 20. The second seal ring 42 is formed continuously to surround the analog circuit 30. In this case, there is also concern about propagation of noise generated in the digital circuit 20 through the first and second seal rings 41 and 42 to the analog circuit 30, which is however reduced by the high-resistance region described above.

FIG. 7 illustrates a fourth variation of the semiconductor integrated circuit 10 of FIG. 1. In FIG. 7, the semiconductor integrated circuit 10 is comprised of a first semiconductor integrated circuit 11 and a second semiconductor integrated circuit 12. The first semiconductor integrated circuit 11 includes a first semiconductor substrate on which the digital circuit 20 is formed. The second semiconductor integrated circuit 12 includes a second semiconductor substrate on which the analog circuit 30 is formed. The first seal ring 41 is formed continuously on the first semiconductor substrate to surround the digital circuit 20. The second seal ring 42 is formed continuously on the second semiconductor substrate to surround the analog circuit 30. In this case, there is also concern about propagation of noise generated in the digital circuit 20 through the first and second seal rings 41 and 42 to the analog circuit 30, which is however reduced by the high-resistance region described above.

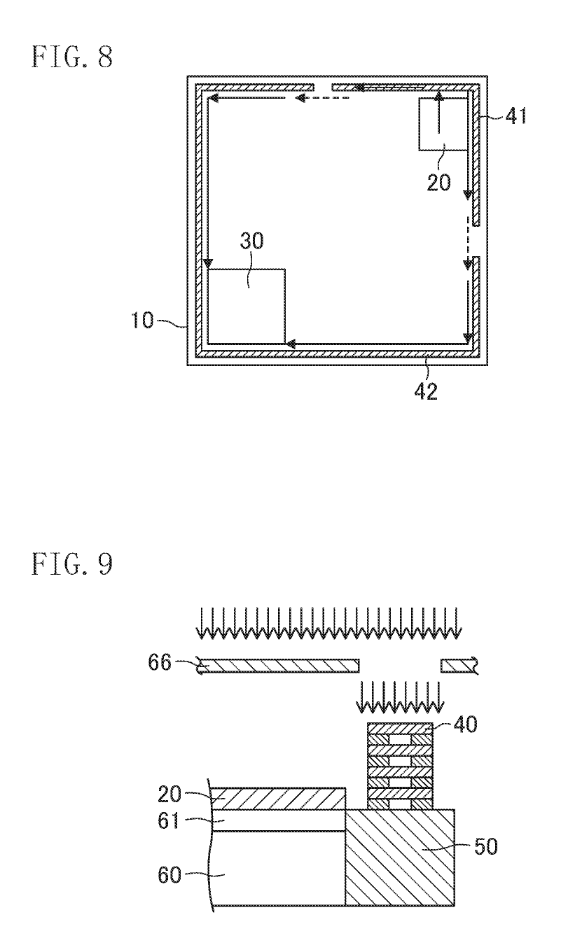

FIG. 8 illustrates a fifth variation of the semiconductor integrated circuit 10 of FIG. 1. In FIG. 8, the seal rings 41 and 42 are formed discontinuously on a single semiconductor substrate on four sides surrounding the digital circuit 20 and the analog circuit 30. In this case, not only the high-resistance region described above but also the discontinuous portions of the seal rings 41 and 42 reduce noise propagation.

FIG. 9 illustrates an exemplary method of forming the high-resistance region 50 in FIG. 2C. In FIG. 9, after the seal ring 40 has been formed, an ion implantation mask 66 made of, for example, metal is aligned, and then part of the semiconductor substrate 60 is selectively irradiated with helium ions to have a high resistance. The helium ions are implanted into the semiconductor substrate 60, thereby causing defects in the crystal lattice of the semiconductor substrate 60. This increases effective resistivity. The high-resistance region 50 formed in this manner contains helium used for ion irradiation on part of the semiconductor substrate 60 to increase resistance, and has a resistivity ten times or more as high as that of the surrounding region. This method is advantageous in forming the high-resistance region 50 right under the seal ring 40 even after the seal ring 40 has been formed. The ions for the irradiation may be hydrogen ions instead of helium ions.

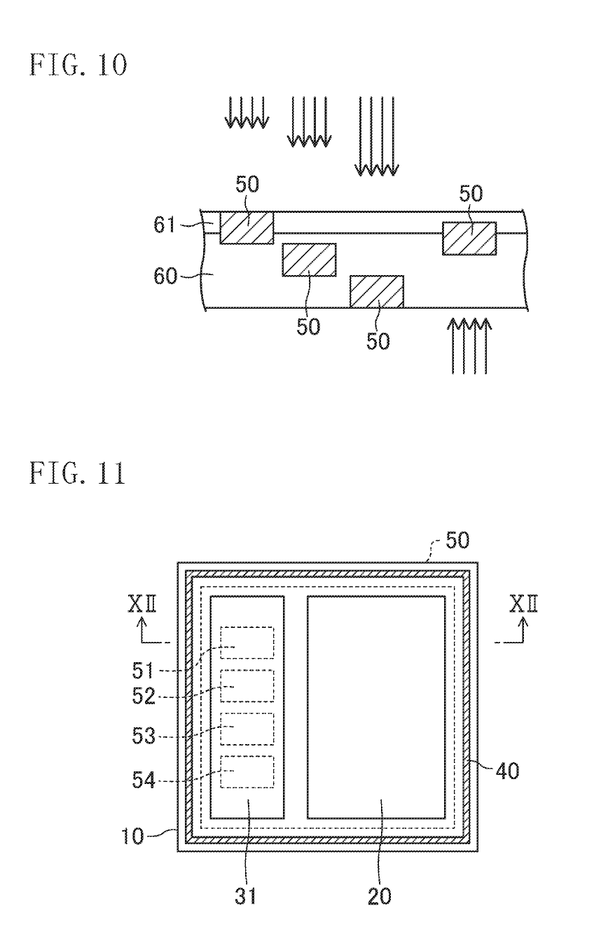

FIG. 10 illustrates a variation of the method of forming the high-resistance region 50 shown in FIG. 9. An ion accelerating voltage may be adjusted to increase the resistance of the portion of the semiconductor substrate 60 at a predetermined depth as shown in FIG. 10. The dosage may be adjusted to determine how much the resistivity is to be increased. The semiconductor substrate 60 may be irradiated with ions from the back surface to form the high-resistance region 50.

The isolation insulating layer 65, which is an STI region formed in the semiconductor substrate 60, has a thickness of about 0.3 μm in a recent typical manufacturing process. If the seal ring 40 is formed on the isolation insulating layer 65, low-frequency noise is effectively reduced, since the isolation insulating layer 65 has a significantly high resistance. However, the capacitance of the layer with such a thickness of about 0.3 μm is too high to reduce high-frequency noise effectively.

By contrast, as in the present disclosure, if the seal ring 40 is provided on the high-resistance region 50, which has been formed by ion irradiation, the thickness of the high-resistance region 50 may easily be set to be greater than that of the isolation insulating layer 65 by controlling the conditions of ion irradiation. This increases resistance and reduces capacitance at the same time, resulting in reduction in both the low- and high-frequency noise.

Simple calculation was performed on the supposition that the isolation insulating layer 65 had a thickness of about 0.3 μm. With an increase in the resistivity of the high-resistance region 50 to about 200 Ω·cm, the present disclosure worked more advantageously than the case where the seal ring 40 was formed on the isolation insulating layer 65, even if the high-resistance region 50 had a thickness of about 0.5 μm. In some manufacturing processes in which the surface of the semiconductor substrate 60 had a resistivity of about 10 to 50 Ω·cm, the present disclosure worked more advantageously where the resistance of the high-resistance region 50 was increased to be as approximately 20 times as high as that of the semiconductor substrate 60.

### Second Embodiment

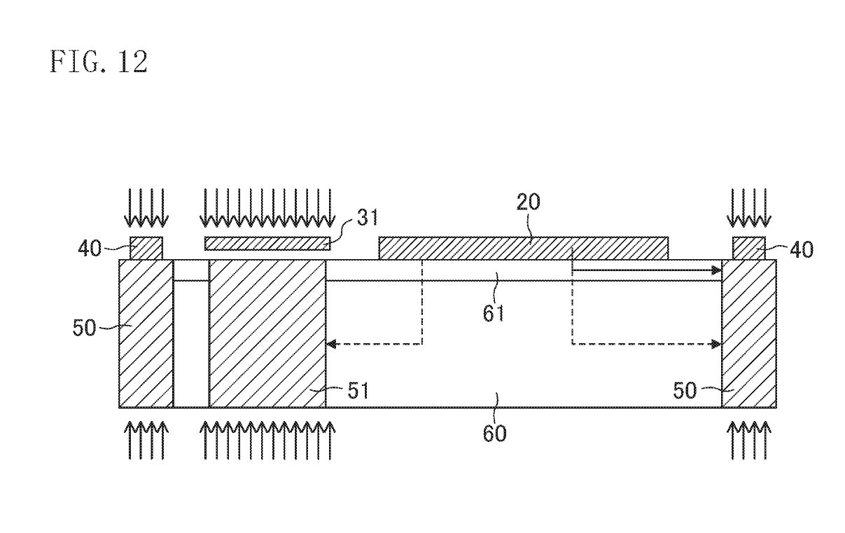

FIG. 11 is a plan view of a semiconductor integrated circuit according to a second embodiment of the present disclosure. FIG. 12 is an enlarged cross-sectional view taken along the plane XII-XII of FIG. 11. A semiconductor integrated circuit 10 according to this embodiment includes a semiconductor substrate 60 and an n-well 61. The semiconductor substrate 60 is made of, for example, p-type semiconductor. The n-well 61 is formed by implanting dopant ions into the surface of the semiconductor substrate 60. A digital circuit 20 and an analog circuit 31 are formed on the semiconductor substrate 60. The digital circuit 20 may serve as a noise source. The analog circuit 31 includes a plurality of on-chip inductors, which are passive elements, to be influenced by noise. A seal ring 40 is further formed on the semiconductor substrate 60 to surround the digital circuit 20 and the analog circuit 31. A high-resistance region 50 is formed in the semiconductor substrate 60 right under the seal ring 40. This high-resistance region 50 is formed to have a higher resistivity than the surrounding region by irradiating the semiconductor substrate 60 with ions. In addition, high-resistance regions 51, 52, 53, and 54 are formed in the semiconductor substrate 60 right under the respective on-chip inductors of the analog circuit 31. These high-resistance regions 51, 52, 53, and 54 are also formed to have a higher resistivity than the surrounding region by irradiating the semiconductor substrate 60 with ions.

In the second embodiment, the high-resistance regions 51, 52, 53, and 54 reduce the propagation of noise leaking into the on-chip inductors of the analog circuit 31. As a result, the noise resistance of the on-chip inductors increases. The high-resistance regions 51, 52, 53, and 54 right under the respective on-chip inductors of the analog circuit 31 may be formed by the same process as the high-resistance region 50 right under the seal ring 40. This does not require any additional cost as compared to the first embodiment.

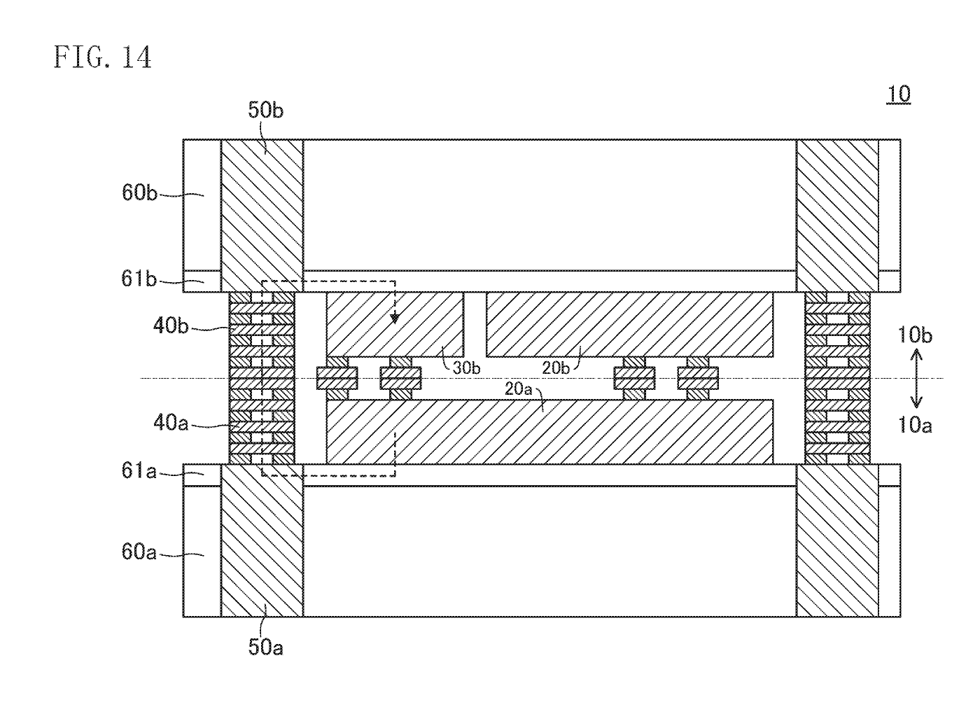

FIG. 13 illustrates a variation of the semiconductor integrated circuit 10 of FIG. 11. For example, a high-resistance region 55 is formed right under a capacitor in which an insulating layer is interposed between two metal layers 70 and 71, thereby increasing the noise resistance of the capacitor. A high-resistance region 56 is formed right under a gate capacitor, in which a metal layer 72 is formed on a doped region 64, thereby increasing the noise resistance of the gate capacitor. A high-resistance region 57 is formed right under a signal line of a metal layer 73, thereby increasing the noise resistance of the signal line.

### Third Embodiment

FIG. 14 is a cross-sectional view of a semiconductor integrated circuit according to a third embodiment of the present disclosure. A semiconductor integrated circuit 10 of FIG. 14 is formed by bonding a first semiconductor integrated circuit 10a to a second semiconductor integrated circuit 10b. The first semiconductor integrated circuit 10a includes a first semiconductor substrate 60a on which a digital circuit 20a is formed. The second semiconductor integrated circuit 10b includes a second semiconductor substrate 60b on which a digital circuit 20b and an analog circuit 30b are formed. An n-well 61a is formed on the surface of the first semiconductor substrate 60a. An n-well 61b is formed on the surface of the second semiconductor substrate 60b. A first seal ring 40a is formed on the first semiconductor substrate 60a to surround the digital circuit 20a. A second seal ring 40b is formed on the second semiconductor substrate 60b to surround the digital circuit 20b and the analog circuit 30b. The first seal ring 40a and the second seal ring 40b are in contact with each other to be electrically conductive with each other.

A first high-resistance region 50a is formed in the first semiconductor substrate 60a right under the first seal ring 40a. A second high-resistance region 50b is formed in the second semiconductor substrate 60b right under the second seal ring 40b. The first and second high-resistance regions 50a and 50b are each formed to have a higher resistivity than the surrounding region by irradiating the first and second semiconductor substrates 60a and 60b, respectively, with ions. There is concern about propagation of noise generated in the digital circuit 20a on the first semiconductor substrate 60a through the first and second seal rings 40a and 40b to the analog circuit 30b on the second semiconductor substrate 60b, which is however reduced by the first and second high-resistance regions 50a and 50b.

Even if the digital circuit 20b is not formed on the second semiconductor substrate 60b, propagation of noise from the digital circuit 20a on the first semiconductor substrate 60a to the analog circuit 30b on the second semiconductor substrate 60b will not be influenced.

While noise propagation from a digital circuit to an analog circuit has been described in the first to third embodiments, the scope of the present disclosure is not limited thereto. The present disclosure is also applicable to reduction in noise propagating from an analog circuit to another analog circuit, for example.

As can be seen from the foregoing description, the semiconductor integrated circuit according to the present disclosure includes a seal ring achieving excellent high-frequency isolation, and thus useful as a semiconductor integrated circuit including a digital circuit and an analog circuit in combination, for example.

What is claimed is:

1. A semiconductor integrated circuit comprising:
a semiconductor substrate;
a first circuit formed on the semiconductor substrate;
a seal ring formed on the semiconductor substrate to surround at least part of the first circuit; and
a high-resistance region formed on a propagation path of noise leaking out of or into the first circuit through the seal ring in the semiconductor substrate to have a higher resistivity than a surrounding region, wherein
the high-resistance region is formed by irradiating the semiconductor substrate with ions.

2. A semiconductor integrated circuit comprising:
a semiconductor substrate;
a first circuit formed on the semiconductor substrate;
a seal ring formed on the semiconductor substrate to surround at least part of the first circuit; and
a high-resistance region formed on a propagation path of noise leaking out of or into the first circuit through the seal ring in the semiconductor substrate to have a higher resistivity than a surrounding region, wherein
the high-resistance region contains hydrogen or helium.

3. The semiconductor integrated circuit of claim 1, wherein
the resistivity of the high-resistance region is ten times or more as high as that of the surrounding region.

4. The semiconductor integrated circuit of claim 1, wherein
the high-resistance region is located within a depth of 10 μm from a surface of the semiconductor substrate.

5. The semiconductor integrated circuit of claim 1, wherein
the high-resistance region is deeper than a well formed in a surface of the semiconductor substrate.

6. The semiconductor integrated circuit of claim 1, wherein
the high-resistance region is located right under the seal ring.

7. The semiconductor integrated circuit of claim 1, wherein
the high-resistance region is located under a silicide layer right under the seal ring.

8. The semiconductor integrated circuit of claim 1, wherein
the high-resistance region is located inside a region right under the seal ring and outside the first circuit.

9. The semiconductor integrated circuit of claim 1, wherein
the high-resistance region includes
a first portion expanding horizontally at a depth of 10 μm or more from a surface of the semiconductor substrate, and
a second portion extending vertically from the surface of the semiconductor substrate to the first portion inside a region right under the seal ring and outside the first circuit.

10. The semiconductor integrated circuit of claim 1, wherein
the first circuit includes
a digital circuit serving as a noise source, and
an analog circuit influenced by noise.

11. The semiconductor integrated circuit of claim 10, comprising:
a first semiconductor integrated circuit including a first semiconductor substrate on which a digital circuit is formed; and
a second semiconductor integrated circuit including a second semiconductor substrate on which an analog circuit is formed, wherein
the seal ring includes
a first seal ring formed continuously on the first semiconductor substrate to surround the digital circuit, and
a second seal ring formed continuously on the second semiconductor substrate to surround the analog circuit.

12. The semiconductor integrated circuit of claim 1, wherein
the seal ring and the high-resistance region are formed continuously to surround the first circuit.

13. The semiconductor integrated circuit of claim 1, wherein
the seal ring is formed continuously to surround the first circuit, and
the high-resistance region is formed discontinuously right under the seal ring.

14. The semiconductor integrated circuit of claim 1, further comprising:
a passive element formed on the semiconductor substrate; and
a high-resistance region formed right under the passive element, wherein
the high-resistance region right under the passive element is formed to have a higher resistivity than a surrounding region by irradiating the semiconductor substrate with ions.

15. The semiconductor integrated circuit of claim 2, wherein
the resistivity of the high-resistance region is ten times or more as high as that of the surrounding region.

16. The semiconductor integrated circuit of claim 2, wherein
the high-resistance region is located within a depth of 10 μm from a surface of the semiconductor substrate.

17. The semiconductor integrated circuit of claim 2, wherein
the high-resistance region is deeper than a well formed in a surface of the semiconductor substrate.

18. The semiconductor integrated circuit of claim 2, wherein
the high-resistance region is located right under the seal ring.

19. The semiconductor integrated circuit of claim 2, wherein
the high-resistance region is located inside a region right under the seal ring and outside the first circuit.

20. The semiconductor integrated circuit of claim 2, further comprising:
a passive element formed on the semiconductor substrate; and
a high-resistance region formed right under the passive element, wherein
the high-resistance region right under the passive element is formed to have a higher resistivity than the surrounding region by irradiating the semiconductor substrate with ions.
